(19) United States
(12) Patent Application Publication
(10) Pub. No.: US 2004/0206998 A1
(43) Pub. Date: Oct. 21, 2004

(54) Semiconductor device having a roughened surface electrode and method of manufacturing the same

(75) Inventor: Masatoshi Anma, Tokyo (JP)

Correspondence Address: BURNS DOANE SWECKER & MATHIS L L P, POST OFFICE BOX 1404, ALEXANDRIA, VA, 22313-1404, US

(73) Assignee: RENESAS TECHNOLOGY CORP.

(21) Appl. No.: 10/646,762

(22) Filed: Aug. 25, 2003

(30) Foreign Application Priority Data
Aug. 26, 2002 (JP) 2002-244870

(51) Int. Cl. H01L 27/108

(52) U.S. Cl. 257/306

(57) ABSTRACT

An opening is defined in an interlayer insulating film, and an amorphous silicon film is formed on the opened interlayer film. Silicon growth nuclei are formed on the amorphous silicon film. The silicon growth nuclei are heat-treated to form a surface-roughened polycrystallized silicon film so that surface roughness of a reverse side of a silicon growth nuclei forming surface increases. The polycrystallized silicon film on the upper surface of the interlayer film is removed to form a concave surface-roughened cylinder. The interlayer film is removed to form a cylindrical surface-roughened electrode

### FIELD OF THE INVENTION

The present invention relates to a semiconductor device having a roughened surface electrode such as a capacitor structure and a manufacturing method thereof.

### BACKGROUND

FIG. 8 is a cross-sectional view showing a fragmentary portion of a cylindrical capacitor electrode structure employed in a memory device such as a DRAM as a conventional semiconductor device.

In FIG. 8, reference numerals 101 indicate conductive plugs for connecting to a lower memory cell transistor or the like, reference numeral 102 indicates an etching stopper film, and reference numerals 103 indicate capacitor electrodes whose surface areas are enlarged by a surface-roughening technology.

FIGS. 9(a) through 9(h) are respectively cross-sectional views showing a method of manufacturing the semiconductor device shown in FIG. 8. While FIG. 8 shows a state in which the capacitor electrodes 103 are arrayed two, a description will be typically made here, of a case in which one of the two is formed.

In FIG. 9(a), an interlayer insulating film 104 is first deposited on a stopper film 102 on a plug 101. In FIG. 9(b), an opening 106 is defined in the interlayer film 104 by a dry etching method. In FIG. 9(c), an amorphous silicon film 107 is next deposited on the interlayer film 104 so as to cover the inner surface of the opening 106. In FIG. 9(d), the amorphous silicon film 107 formed on the upper surface of the interlayer film 104 is removed to form a concave amorphous silicon film 108. Further, the interlayer film 104 is removed to obtain a cylindrical amorphous silicon film 109 as shown in FIG. 9(e).

Next, silicon growth nuclei 110 used for migrating silicon are formed on the cylindrical amorphous silicon film 109 in FIG. 9(f). At this time, as indicated at the right portion of the stopper film 102 in the same figure (f), a portion might occur in which the density of the silicon growth nuclei 110 is high. When the amorphous silicon film is migrated at this state shown in FIG. 9(g), a cylindrical surface-roughened electrode 111 is formed and at the same time rough surface grains 112 are grown on the stopper film 102. Next, the rough surface grains 112 on the stopper film 102 are removed by dry etchback or the like in FIG. 9(h) to finally obtain a capacitor electrode 113.

Upon manufacture of the conventional semiconductor device, a short circuit might be developed between the adjacent capacitor electrodes 113 due to the growth of the rough surface grains 112 on the stopper film 102 as shown in FIG. 9(g). Therefore, in order to avoid the formation of the silicon growth nuclei 110 on the stopper film 102 between the capacitor electrodes 113, the silicon growth nuclei 110 are formed under a condition or environment holding high selective growth capability. It is however difficult to obtain perfect selectivity.

When dry etchback is performed to remove the rough surface grains 112 on the stopper film 102, the surface of the surface-roughened electrode 111 surface-roughened to enlarge the capacitance of a capacitor becomes gentle and hence an increase in the area as for a capacitor lower electrode cannot be achieved.

The diameter of each rough surface grain cannot be made greater to avoid degradation of coverage of a dielectric film on the cylindrical inner side of the cylindrical capacitor electrode 113 and opposite electrodes.

When a pillar capacitor structure is formed to ensure the strength of the capacitor electrode in the prior art, surface-roughening is performed after the formation of each pillar electrode so that rough surface grains are grown between the adjacent pillar electrodes, thereby developing a short circuit between the pillar electrodes.

Further, it has been difficult to apply an effective surface roughening method to a capacitor electrode in case a metal material is used.

The present invention has been made to solve such conventional problems and aims to provide a semiconductor device, and a manufacturing method thereof, capable of preventing the occurrence of a short circuit between capacitor electrodes.

The present invention also aims to provide a semiconductor device, and a manufacturing method thereof, capable of ensuring coverage of a dielectric film on an inner side of a cylindrical electrode in a cylindrical capacitor electrode or opposite electrodes

Further, the present invention aims to provide a semiconductor device, and a manufacturing method thereof, that improve a physical strength of a cylindrical (concave) or columnar (pillar) capacitor electrode.

Furthermore, the present invention aims to provide a semiconductor device, and a manufacturing method thereof, capable of reducing an interface resistance between a capacitor electrode and a connecting plug or reducing the resistance of the capacitor electrode per se.

### SUMMARY OF THE INVENTION

According to one aspect of the present invention, a semiconductor device comprises an electrode formed of a flat plate portion at a bottom thereof and a cylindrical portion which extends up continuously from the flat plate portion and whose one side is open. A rough-surface grain diameter of an outer surface of the electrode is formed so as to be larger than a rough-surface grain diameter of an inner surface thereof.

In another aspect of the present invention, in the semiconductor device, a conductor film may be preferably formed along the inner surface of the electrode.

In another aspect of the present invention, in the semiconductor device, the inner side of the cylindrical portion may be buried with a conductive film.

In another aspect of the present invention, in the semiconductor device, the flat plate portion at the bottom of the electrode may be removed and the inner side of the cylindrical portion is buried with a conductive film.

According to another aspect of the present invention, in a method of manufacturing a semiconductor device, an opening is formed in an interlayer insulating film disposed on a substrate. An amorphous silicon film is formed in a concave form along an inner surface of the opening. Silicon growth nuclei is formed on the surface of the amorphous silicon film. The amorphous silicon film is heat-treated to migrate silicon to polycrystallize the silicon film. The polycrystallized silicon film on the interlayer insulating film is removed. Then, the interlayer insulating film is removed to form a cylindrical surface-roughened electrode.

Other and further objects, features and advantages of the invention will appear more fully from the following description.

### BRIEF DESCRIPTION OF THE DRAWINGS

FIGS. 1(a) through 1(d) shows a surface-roughening process of the present invention.

FIG. 2 is a fragmentary cross-sectional view showing one example of a semiconductor device having a surface-roughened cylindrical capacitor electrode structure.

FIGS. 3(a) through 3(f) are respectively diagrams showing a method of manufacturing a semiconductor device and shows a fragmentary cross-sectional views of a capacitor electrode and its a peripheral portion, according to a first embodiment of the present invention.

FIGS. 4(a) through 4(g) are respectively diagrams showing a method of manufacturing a semiconductor device and shows a fragmentary cross-sectional views of a capacitor electrode and its a peripheral portion, according to a second embodiment of the present invention.

FIGS. 5(a) through 5(i) are respectively diagrams showing a method of manufacturing a semiconductor device and shows a fragmentary cross-sectional views of a capacitor electrode and its a peripheral portion, according to a third embodiment of the present invention.

FIGS. 6(a) through 6(g) are respectively diagrams showing a method of manufacturing a semiconductor device and shows a fragmentary cross-sectional views of a capacitor electrode and its a peripheral portion, according to a fourth embodiment of the present invention.

FIGS. 7(a) through 7(h) are respectively diagrams showing a method of manufacturing a semiconductor device and shows a fragmentary cross-sectional views of a capacitor electrode and its a peripheral portion, according to a fourth embodiment of the present invention.

FIG. 8 is a cross-sectional view showing a fragmentary portion of a cylindrical capacitor electrode structure employed in a memory device such as a DRAM as a conventional semiconductor device.

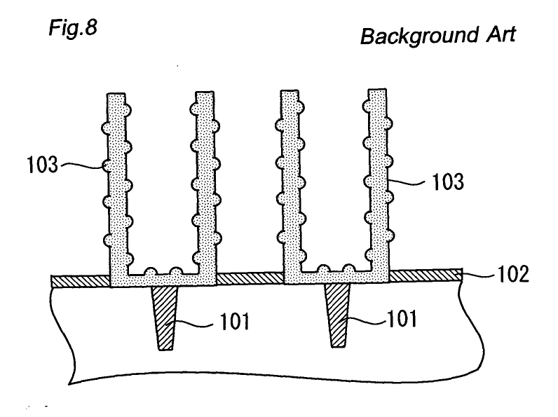

FIGS. 9(a) through 9(h) are respectively cross-sectional views showing a method of manufacturing the semiconductor device shown in FIG. 8.

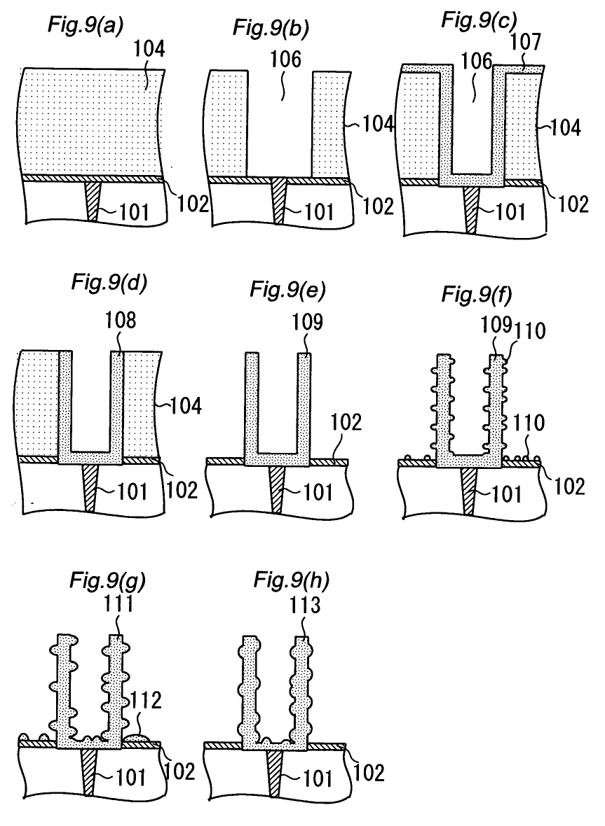

### DETAILED DESCRIPTION OF THE PREFERRED EMBODIMENTS

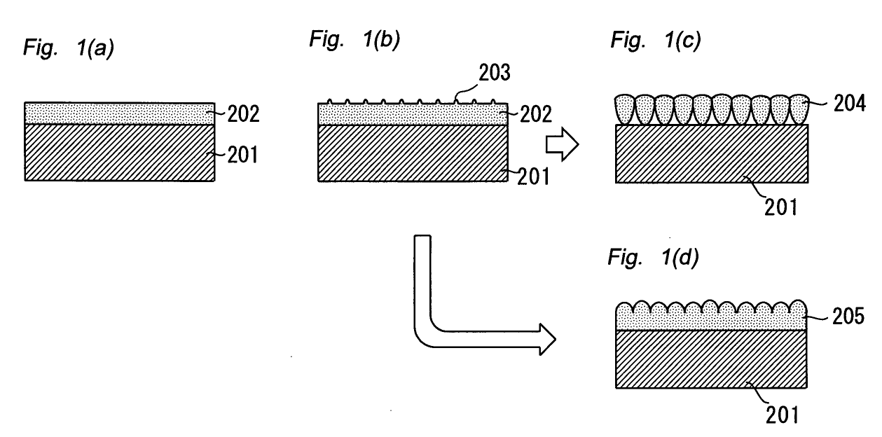

A surface-roughening process of the present invention will first be described with reference to FIGS. 1(a) through 1(d).

In FIG. 1(a), an amorphous silicon film 202 is formed on a silicon film 201 as a base or underlying film. In FIG. 1(b), silicon growth nuclei 203 is formed on the upper surface of the amorphous silicon film 202. In FIG. 1(c), a surface-roughened silicon film 204 is formed through rough-surface growth and polycrystallization under high-temperature treatment. When silicon migration is caused within the amorphous silicon film 202 on the basis of the silicon growth nuclei 203 or from the silicon growth nuclei 203, high-temperature treatment is made thereto at preferably 750° C. to 800° C., and more preferably 770° C. to 800° C., to thereby enlarge a surface area of a rough surface on the reverse or back side, i.e. the opposite side of the upper surface formed with the growth nuclei 203 in the case of the surface-roughened silicon film 204. In other words, a rough-surface grain diameter of a lower surface of the surface-roughened silicon film 204 is greater than a rough-surface grain diameter of an upper surface thereof. According to the present invention as described above, when the migration is caused in the amorphous silicon film, the amorphous silicon film is subjected to high-temperature treatment at preferably 750° C. to 800° C., and more preferably 770° C. to 800° C., to thereby make it possible to enlarge the surface area of the reverse side of the surface formed with the migration nuclei. FIG. 1(d) is a conventional example illustrated for comparison. In a conventional surface-roughening process, a nuclei-added upper surface of a surface-roughened silicon film 205 is mainly surface-roughened.

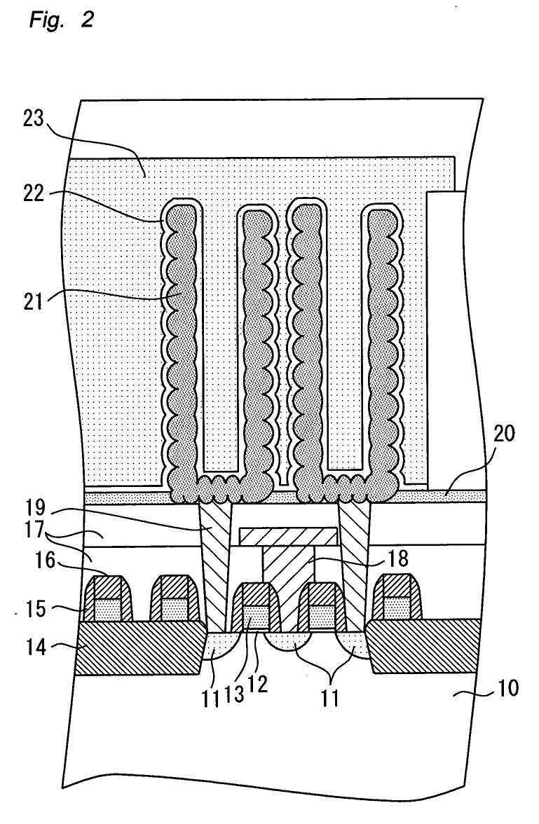

FIG. 2 is a fragmentary cross-sectional view showing one example of a semiconductor device having a surface-roughened cylindrical capacitor electrode structure, to which the present invention is applied.

In FIG. 2, the semiconductor device includes a semiconductor substrate 10, a source/drain diffusion layer 11, a gate insulating film 12, a gate electrode 13, a element isolation insulating film 14, sidewalls 15, a mask insulating film 16, interlayer insulating films 17, a bit line contact 18, and storage node contacts (conductive plugs) 19 which are conductive plugs for connecting a lower transistor and a capacitor electrode, respectively. The semiconductor device further includes a stopper film 20, and a capacitor electrode (storage node electrode) 21 used as a first electrode, which is a surface-roughened cylindrical silicon electrode or the like formed according to the present invention. The semiconductor device further includes a capacitor dielectric film 22, and a cell plate electrode 23 used as a second electrode.

The embodiment of the present invention will be described below based on the drawings while the semiconductor device having the surface-roughened capacitor electrode structure is being taken for example. While the present embodiment will be described here as a semiconductor device and a manufacturing method thereof, it may be grasped as a method of manufacturing a surface-roughened electrode (capacitor electrode) or a method of manufacturing a capacitor element.

### First Embodiment

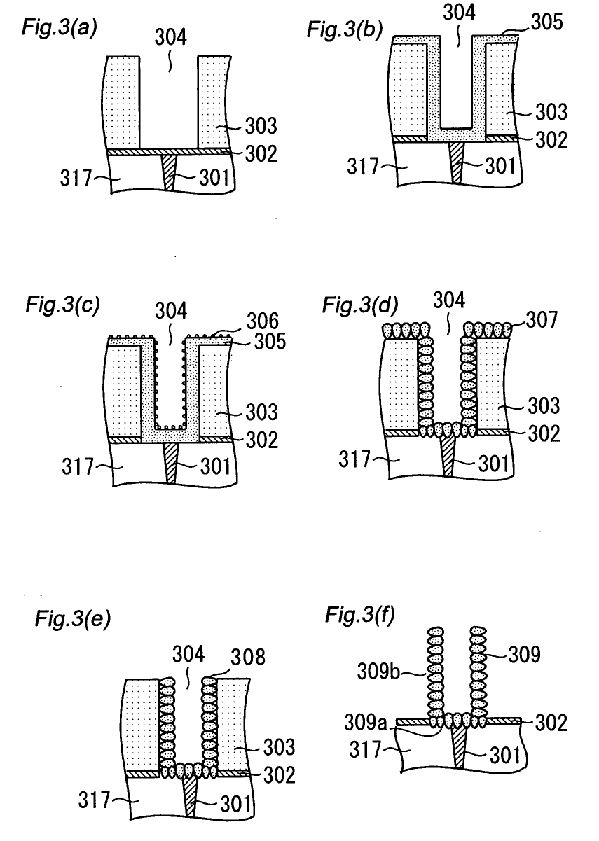

FIGS. 3(a) through 3(f) are respectively diagrams showing a method of manufacturing a semiconductor device, according to a first embodiment of the present invention and fragmentary cross-sectional views showing a capacitor electrode and its a peripheral portion alone.

The method of manufacturing the semiconductor device, according to the first embodiment, particularly, a surface-roughened cylindrical electrode, a structure of a capacitor using the electrode and a manufacturing method thereof will be described with reference to FIGS. 3(a) through 3(f).

In FIG. 3(a), a plug-shaped conductor 301 connected to a conductive portion (not shown) such as a downward transistor or the like is formed in a base interlayer insulating film 317 on a substrate (not shown). A silicon nitride film 302 used as an etching stopper film is formed on the conductor plug 301. Further, an interlayer insulating film 303 formed of a silicon oxide film (called “interlayer film” for short) is formed thereon by a CVD method or the like. Thereafter, the interlayer film 303 is selectively removed by using a photolithography technology and a dry etching technology to form an opening 304. Further, the etching stopper film 302 at the bottom of the opening 304 is removed so that the opening 304 reaches the conductive plug 301.

Next, as shown in FIG. 3(b), an amorphous silicon film 365 is formed on the interlayer film 303 by the CVD method. The amorphous silicon film 305 is formed in a recess fashion along an inner surface of the opening 304.

Next, as shown in FIG. 3(c), silicon growth nuclei 306 are created or formed on the surface of the amorphous silicon film 305 by gas containing Si such as Si₂H₆ or the like. Subsequently, heat treatment is applied thereto at a temperature ranging from, for example, 750° C. to 800° C. to migrate silicon.

At this time, migration is generated up to the back side of the nuclei-applied surface under high-temperature processing at 750° C. to 800° C. as typically shown in FIG. 3(d) to polycrystallize the silicon, thereby forming a polycrystallized silicon film 307. Namely, amorphous silicon is migrated based on the growth nuclei 306 until morphology of the surface corresponding to the side reverse to the surface formed with the growth nuclei changes. Namely, amorphous silicon is migrated based on the growth nuclei 306 until morphology changes on the reverse surface opposite to the surface formed with the growth nuclei.

Next, as shown in FIG. 3(e), the polycrystallized silicon film 307 on the interlayer film 303 except for the opening 304 is removed by a CMP method or a dry etching method to form a surface-roughened cylinder 308 of recessed or concave type polycrystal silicon. Next, the interlayer film 303 is removed by chemical containing vapor-phase or liquid-phase hydrofluoric acid as shown in FIG. 3(f) to thereby form a cylindrical surface-roughened electrode 309. The cylindrical surface-roughened electrode 309 is formed of a flat plate portion 309a at its bottom and a cylindrical portion 309b which extends up continuously from the flat plate portion 309a and whose one side is made open. Further, the cylindrical surface-roughened electrode 309 has outer and inner surfaces subjected to a surface-roughening process and is formed such that a rough-surface grain diameter of its outer surface is larger than that of its inner surface.

Reducing the inner surface roughness in this way makes it possible to prevent degradation of coverage where a dielectric film or opposite electrodes are formed on the cylindrical inner side.

As described above, the present embodiment can prevent a short circuit between adjacent capacitor electrodes by keeping the interlayer film 303 as it is during surface-roughening processing of the surface of the electrode material. Therefore, countermeasures for selectively forming the silicon growth nuclei is not needed as in the prior art. Since the inner and outer sides of the cylindrical surface-roughened electrode 309 can be changed in surface roughness, the coverage of the dielectric or opposite electrodes placed on the cylindrical inner side can be ensured by reducing the surface roughness of the cylindrical inner side. Further, the capacitance of the capacitor can be ensured by increasing the surface roughness of the cylindrical outer side.

Incidentally, as a semiconductor manufacturing process, a dielectric film is formed on the surface of the cylindrical surface-roughened electrode 309 as a first electrode shown in FIG. 3(f), and opposite electrodes as a second electrode is further formed thereon, thereby forming a capacitive element. Since its structure and manufacturing method are understood from FIG. 2 and the conventional method may be adopted, their detailed description is omitted.

While nuclei are attached from the cylindrical inner side of an electrode material upon formation of a cylindrical surface-roughened electrode in the present embodiment as described above, the cylindrical outer side is made uneven and its inner side is crushed to reduce irregularities under rough-surface growth at a high temperature, thereby making it possible to form a cylindrical capacitor structure whose outer side is surface-roughened.

In the present embodiment as well, rough-surface growth nuclei are formed prior to the removal of an interlayer film in a cylindrical capacitor electrode to thereby avoid the growth of rough surface grains between the adjacent cylindrical capacitor electrodes, thus making it possible to avoid the occurrence of a short circuit between the cylindrical capacitor electrodes.

A structure of the present embodiment will next be explained in a summarized form as follows:

A surface-roughened electrode according to the present embodiment corresponds to the surface-roughened electrode (first electrode) 309 formed of a flat plate portion 309a at its bottom and a cylindrical portion 309b which extends up continuously from the flat plate portion 309a and whose one side is made open as shown in FIG. 3(e) and FIG. 3(f). The surface-roughened electrode is one in which the surface thereof is subjected to surface-roughening processing and which is formed such that the rough-surface grain diameter of its outer surface is greater than that of its inner surface.

A capacitive element according to the present embodiment comprises the first electrode 309 formed as described above, the dielectric film formed continuously from the inner surface of the first electrode to the outer surface its cylindrical portion, and the second electrode formed so as to be opposed to the first electrode with the dielectric film interposed therebetween.

Further, as an example according to the present embodiment, a semiconductor device may be mentioned in which the above-described capacitive element is formed on an underlying interlayer insulating film on a semiconductor substrate, and a first electrode of the capacitive element and a conductive plug formed in the underlying interlayer insulating film are connected.

A manufacturing method according to the first embodiment will be described en bloc as follows:

In a method of manufacturing the surface-roughened electrode, according to the first embodiment, the conductive plug 301 is first formed in the base interlayer insulating film 317 on the substrate as a preliminary stage. The etching stopper film 302 is formed on the base interlayer insulating film 317 and the conductive plug 301. The interlayer insulating film 303 is formed on the etching stopper film 302. Next, the interlayer insulating film 303 and the etching stopper film 302 are selectively removed to define the opening 304 which reaches the conductive plug 301 (FIGS. 3(a) and 3(b)). The amorphous silicon film 305 is formed in the concave form along the inner surface of the opening 304 (FIG. 3(b)). The silicon growth nuclei 306 are formed on the surface of the amorphous silicon film 305 (FIG. 3(c)). The amorphous silicon film is heat-treated so that silicon is migrated and polycrystallized to form the polycrystallized silicon film 307 (FIG. 3(d)). The polycrystallized silicon film 307 on the interlayer insulating film 303 is removed (FIG. 3(e)), and the interlayer insulating film 303 is removed to form the cylindrical surface-roughened electrode 309 (FIG. 3(f)).

### Second Embodiment

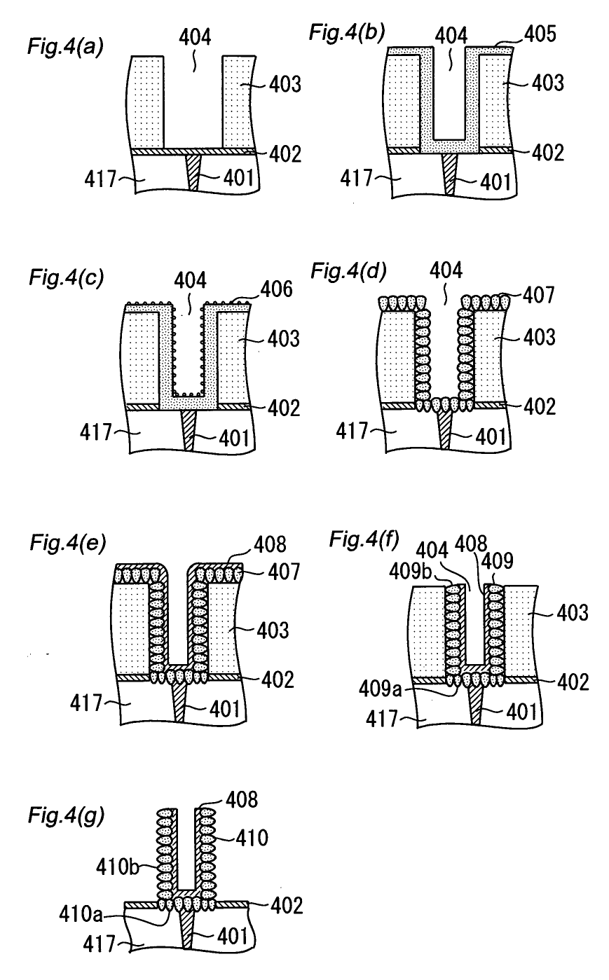

FIGS. 4(a) through 4(g) are respectively diagrams showing a method of manufacturing a semiconductor device, according to a second embodiment of the present invention and fragmentary cross-sectional views showing a capacitor electrode and its a peripheral portion alone.

The method of manufacturing the semiconductor device, according to the second embodiment, particularly, a surface-roughened cylindrical electrode, a structure of a capacitor using the electrode and a manufacturing method thereof will be described with reference to FIG. 4(a) through 4(g).

In FIG. 4(a), a plug-shaped conductor 401 connected to a lower conductive portion (not shown) is formed in a base or underlying interlayer film 417. A silicon nitride film (stopper film) 402 is formed on the conductor plug 401. Further, an interlayer insulating film 403 formed of a silicon oxide film is formed thereon by a CVD method or the like. Thereafter, an opening 404 is defined in the interlayer film 403 by using a photolithography technology and a dry etching technology. Further, the etching stopper film 402 at the bottom of the opening 404 is removed so that the opening 404 reaches the conductive plug 401.

Next, as shown in FIG. 4(b), an amorphous silicon film 405 is formed on the interlayer film 403 by the CVD method. The amorphous silicon film 405 is formed in a concave form along an inner surface of the opening 404.

Next, as shown in FIG. 4(c), silicon growth nuclei 406 are formed on the amorphous silicon film 405 by gas containing Si such as Si₂H₆ or the like. Subsequently, heat treatment is applied thereto at a temperature ranging from preferably 750° C. to 800° C., and more preferably 770° C. to 800° C., to migrate silicon.

At this time, migration is generated up to the back or reverse side of a nuclei-added surface under high-temperature processing at preferably 750° C. to 800° C., and more preferably 770° C. to 800° C., as typically shown in FIG. 4(d) to bring about silicon polycrystallization, thereby forming a polycrystallized silicon film 407. Namely, amorphous silicon is migrated based on the growth nuclei 406 until morphology is changed on the surface of the reverse side opposite to the surface formed with the growth nuclei. Thus, the polycrystallized silicon film 407 is formed such that upper and inner surfaces thereof decrease in surface roughness and lower and outer surfaces thereof increase in surface roughness.

Next, as shown in FIG. 4(e), a conductor film 408 is formed on the silicon film 407 along its concave shape. As the conductor film 408, silicon, a titanium nitride/titanium laminated film, a ruthenium/titanium nitride/titanium laminated film, tungsten nitride or tungsten nitride/titanium nitride/titanium laminated film, or the like are used. The polycrystallized silicon film 407 is coated with the conductor film 408 to ensure strength thereof at its cylindering later. When the materials other than silicon are used, an increase in the thickness of a dielectric film on the cylindrical inner-wall side due to electrode oxidation or nitridation at a dielectric film forming process can be suppressed.

Next, as shown in FIG. 4(f), the silicon film 407 and conductor film 408 on the interlayer film 403, other than those for the opening 404, are removed by a CMP method or a dry etching method to form a concave surface-roughened cylinder 409.

Next, as shown in FIG. 4(g), the interlayer film 403 is removed by chemical containing vapor-phase or liquid-phase hydrofluoric acid to thereby form a cylindrical surface-roughened electrode 410. The cylindrical surface-roughened electrode 410 is formed of a surface-roughened cylinder 409 formed of a flat plate portion 409a at its bottom and a cylindrical portion 409b which extends up continuously from the flat plate portion 409a and whose one side is made open, and a conductor film 408 formed along its inner surface. Further, the cylindrical surface-roughened electrode 410 has an outer surface subjected to surface-roughening processing and is formed such that a rough-surface grain diameter of its outer surface becomes large.

As described above, the present embodiment can prevent a short circuit between adjacent capacitor electrodes by keeping the interlayer film 403 as it is during surface-roughening processing of the surface of the electrode material without the need to take countermeasures for selectively forming the silicon growth nuclei as in the prior art. Since the conductive film is applied to the cylindrical inner surface of the cylindrical surface-roughened electrode 410, its mechanical strength can be enlarged. The capacitance of the capacitor can be ensured by increasing surface roughness of the outer side of the cylindrical surface-roughened electrode 410.

A structure of the present embodiment will next be explained in a summarized form as follows:

The surface-roughened electrode according to the present embodiment can be grasped as one wherein the conductor film is formed along the inner surface of the surface-roughened electrode (first electrode) shown in FIG. 3(f).

Further, in the present embodiment, there is provided a surface-roughened electrode (first electrode) 410 which is formed of the surface-roughened cylinder 409 having the flat plate portion 409a at its bottom and the cylindrical portion 409b which extends up continuously from the flat plate portion 409a and whose one side is made open, and the conductor film 408 covered along its inner surface. The surface-roughened electrode is one in which the surfaces of the flat plate portion 409a and cylindrical portion 409b of the surface-roughened cylinder 409 are subjected to surface-roughening processing and which is formed such that the rough-surface grain diameter of its outer surface is greater than that of its inner surface.

The manufacturing method according to the second embodiment may also be grasped as follows:

The method of manufacturing the surface-roughened electrode, according to the second embodiment can be grasped as one in which, in the manufacturing method of the first embodiment, a step for forming the conductor film in the concave form along the inner surface of the polycrystallized silicon film is further included following the migration step prior to the step for removing the polycrystallized silicon film.

### Third Embodiment

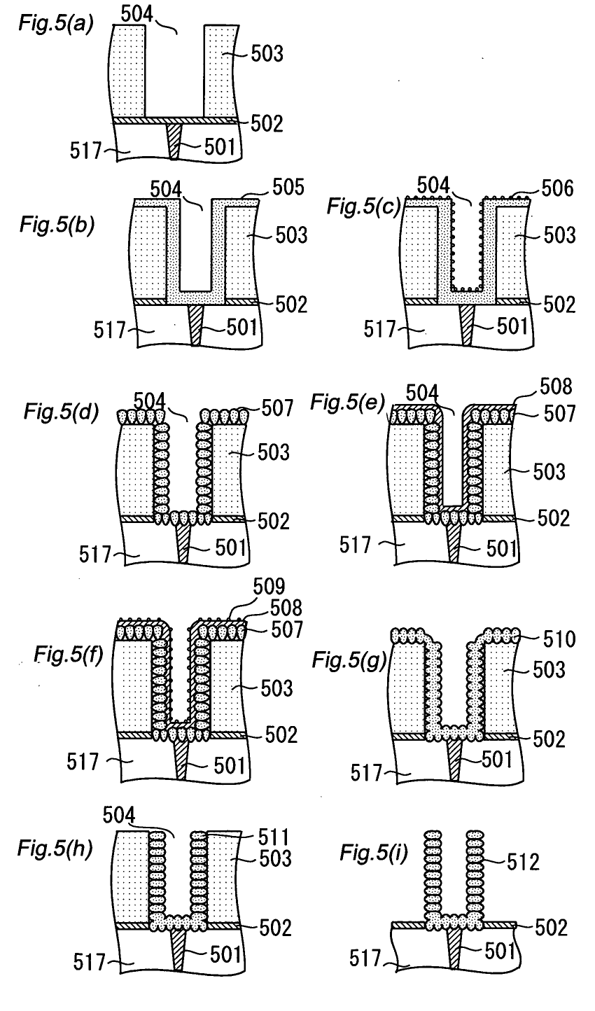

FIGS. 5(a) through 5(i) are respectively diagrams showing a method of manufacturing a semiconductor device, according to a third embodiment of the present invention, and fragmentary cross-sectional views showing a capacitor electrode and its a peripheral portion alone.

The method of manufacturing the semiconductor device, according to the third embodiment, particularly, a surface-roughened cylindrical electrode, a structure of a capacitor using the electrode and a manufacturing method thereof will be described with reference to FIGS. 5(a) through 5(i).

In FIG. 5(a), a plug-shaped conductor 501 connected to a lower conductive portion (not shown) is first formed in a base interlayer film 517. A stopper film (silicon nitride film) 502 is formed on the conductor plug 501. Further, an interlayer insulating film 503 formed of a silicon oxide film is formed thereon by a CVD method or the like. Thereafter, an opening 504 is defined in the interlayer film 503 by using a photolithography technology and a dry etching technology. In addition, the etching stopper film 502 at the bottom of the opening 504 is removed so that the opening 504 reaches the conductive plug 501.

Next, as shown in FIG. 5(b), an amorphous silicon film 505 is formed on the interlayer film 503 by the CVD method. The amorphous silicon film 505 is formed in a recess fashion along an inner surface of the opening 504.

Next, as shown in FIG. 5(c), silicon growth nuclei 506 are formed on the amorphous silicon film 505 by gas containing Si such as Si₂H₆ or the like. Subsequently, heat treatment is applied thereto at a temperature ranging from preferably 750° C. to 800° C., more preferably 770° C. to 800° C., to migrate silicon.

At this time, migration is generated up to the back side of a nuclei-applied surface under high-temperature processing at preferably 750° C. to 800° C., more preferably 770° C. to 800° C., as shown in FIG. 5(d) to polycrystallize the silicon, thereby forming a polycrystallized silicon film 507. Namely, amorphous silicon is migrated based on the growth nuclei until morphology changes on the surface of the reverse side opposite to the surface formed with the growth nuclei. Thus, the polycrystallized silicon film 507 is formed such that upper and inner surfaces thereof decrease in surface roughness and lower and outer surfaces thereof increase in surface roughness.

Next, as shown in FIG. 5(e), an amorphous silicon film (second amorphous silicon film) 508 is formed once again on the polycrystallized silicon film 507 by the CVD method. The amorphous silicon film 508 is formed in a concave form along the shape of the polycrystallized silicon film 507.

Next, as shown in FIG. 5(f), silicon growth nuclei 509 are formed anew on the surface of the amorphous silicon film 508 by gas containing Si such as Si₂H₆ or the like.

As shown in FIG. 5(g), heat treatment is subsequently effected thereon at 700° C. to 790° C. to migrate the amorphous silicon film 508, thereby forming a surface-roughened film 510. However, the surface-roughening temperature of the amorphous silicon film 508 at the second time is set lower than the first surface-roughening temperature of the amorphous silicon film 505 so that increase the surface area on the nuclei-added surface side.

Next, as shown in FIG. 5(h), the polycrystallized silicon film 510 on the interlayer film 503, other than that for the opening 504, is removed by a CMP method or a dry etching method to form a concave surface-roughened cylinder 511.

Next, the interlayer film 503 is removed by chemical containing vapor-phase or liquid-phase hydrofluoric acid as shown in FIG. 5(i) to thereby form a cylindrical surface-roughened electrode 512. The cylindrical surface-roughened electrode 512 is formed of a flat plate portion 512a at its bottom and a cylindrical portion 512b which extends up continuously from the flat plate portion 512a and whose one side is made open. Further, the cylindrical surface-roughened electrode 512 has outer and inner surfaces thereof subjected to surface-roughening processing and is formed such that a rough-surface grain diameter of its outer surface is larger than that of its inner surface. Reducing the inner surface roughness in this way makes it possible to prevent degradation of coverage where a dielectric film or opposition electrodes are formed on the cylindrical inner side.

As described above, the present embodiment can prevent a short circuit between adjacent capacitor electrodes by leaving the interlayer film 503 as it is during surface-roughening processing of the surface of the electrode material without the need to take countermeasures for selectively forming the silicon growth nuclei as in the prior art.

Since the inner and outer sides of the cylindrical surface-roughened electrode 512 can be changed in surface roughness by performing surface roughening of the amorphous silicon in two layers in the present embodiment, the coverage of the dielectric or opposite electrodes placed on the cylindrical inner side can be ensured by reducing the surface roughness of the cylindrical inner side, and the capacitance of the capacitor can be ensured by increasing the surface roughness of the cylindrical outer side.

Next, the manufacturing method according to the third embodiment may also be grasped as follows:

The method of manufacturing the surface-roughened electrode, according to the third embodiment, can be grasped as one in which, in the manufacturing method of the first embodiment, a step for forming a second amorphous silicon film in the concave form along the inner surface of the polycrystallized silicon film and a step for processing the second amorphous silicon film by heat to thereby migrate and polycrystallize silicon are further included following the migration step prior to the step for removing the polycrystallized silicon film.

### Fourth Embodiment

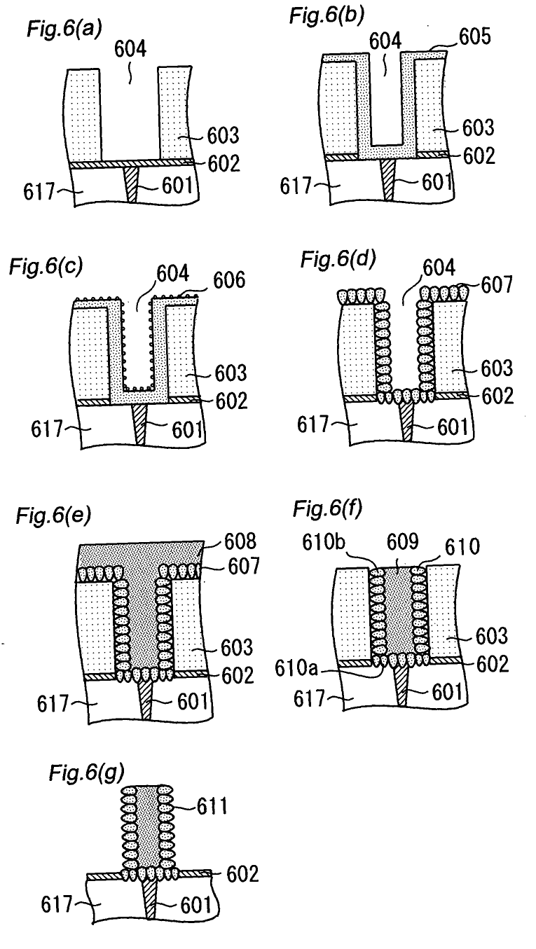

FIGS. 6(a) through 6(g) are respectively diagrams showing a method of manufacturing a semiconductor device, according to a fourth embodiment of the present invention, and fragmentary cross-sectional views showing a capacitor electrode and its a peripheral portion alone.

The method of manufacturing the semiconductor device, according to the fourth embodiment of the present invention, particularly, a surface-roughened cylindrical electrode, a structure of a capacitor using the electrode and a manufacturing method thereof will be described with reference to FIGS. 6(a) through 6(g).

In FIG. 6(a), a plug-shaped conductor 601 connected to a lower conductive portion (not shown) is first formed in a base or underlying interlayer film 617. A stopper film (silicon nitride film) 602 is formed on the conductor plug 601. Further, an interlayer insulating film 603 composed of a silicon oxide film is formed thereon by a CVD method or the like. Thereafter, an opening 604 is defined in the interlayer film 603 by using a photolithography technology and a dry etching technology. Further, the etching stopper film 602 at the bottom of the opening 604 is removed so that the opening 604 reaches the conductive plug 601.

Next, as shown in FIG. 6(b), an amorphous silicon film 605 is formed on the interlayer film 603 by the CVD method. The amorphous silicon film 605 is formed in a recess fashion along an inner surface of the opening 604.

Next, as shown in FIG. 6(c), silicon growth nuclei 606 are formed on the amorphous silicon film 605 by gas containing Si such as Si₂H₆ or the like. Subsequently, heat treatment is made thereto at a temperature ranging from preferably 750° C. to 800° C., more preferably 770° C. to 800° C., to migrate silicon.

At this time, migration is generated up to the back side of a nuclei-applied surface under high-temperature processing at preferably 750° C. to 800° C., more preferably 770° C. to 800° C., as typically illustrated in FIG. 6(d) to polycrystallize the silicon, thereby forming a polycrystallized silicon film 607. Namely, amorphous silicon is migrated based on the growth nuclei until morphology changes at the surface of the reverse side opposite to the surface formed with the growth nuclei. Thus, the polycrystallized silicon film 607 is formed such that upper and inner surfaces thereof decrease in surface roughness and lower and outer surfaces thereof increase in surface roughness. Reducing the inner surface roughness in this way makes it possible to improve coverage where a conductor is embedded in the cylindrical inner side.

Next, as shown in FIG. 6(e), a conductor film 608 is formed on the polycrystallized silicon film 607 so as to bury the opening 604.

Next, as shown in FIG. 6(f), the polycrystallized silicon film 607 and the conductor film 608 on the interlayer film 603 are removed by a CMP method or a dry etching method. Owing to this removal, a columnar or pillar electrode with a conductor 609 embedded in a concave surface-roughened cylinder 610 of the polycrystallized silicon film is formed.

Next, as shown in FIG. 6(g), the interlayer film 603 is removed by chemical containing vapor-phase or liquid-phase hydrofluoric acid to thereby form a pillar surface-roughened electrode 611. Embedding the conductor 609 in the cylindrical inner side of the concave surface-roughened cylinder 610 makes it possible to enhance a physical strength. On the other hand, when, for example, a metal conductor other than silicon is embedded as the conductor film 608, the pillar surface-roughened electrode 611 can be reduced in resistance.

As described above, the present embodiment can prevent a short circuit between adjacent capacitor electrodes by leaving the interlayer film 603 as it is during surface-roughening processing of the surface of the electrode material without the need to take countermeasures for selectively forming the silicon growth nuclei as in the prior art. Increasing the surface roughness of the outer side of the pillar surface-roughened electrode 611 can ensure the capacitance of the capacitor. In the present embodiment, an improvement in the physical strength of the capacitor electrode and a reduction in the resistance of the electrode can be achieved by charging the conductor 609 inside the concave surface-roughened cylinder 610.

A structure of the present embodiment will next be explained in a summarized form as follows:

The surface-roughened electrode according to the present embodiment can be grasped as one in which, in the surface-roughened electrode (first electrode) shown in FIG. 3(f), the inner side of its cylindrical portion is buried with the conductor film.

Further, according to the present embodiment, there is provided a surface-roughened electrode (first electrode) 611 formed of the surface-roughened cylinder 610 having a flat plate portion 610a at its bottom and a cylindrical portion 610b which extends up continuously from the flat plate portion 610a and whose one side is made open, and the conductor film portion 609 which buries the inside of the cylindrical portion 610b. The surface-roughened electrode is one in which the surfaces of the flat plate portion 610a and cylindrical portion 610b of the surface-roughened cylinder 610 are subjected to surface-roughening processing and which is formed such that the rough-surface grain diameter of its outer surface is greater than that of its inner surface.

A capacitive element according to the present embodiment comprises the first electrode 611 formed as described above, a dielectric film formed on the outer surface of the first electrode, and a second electrode formed so as to be opposed to the first electrode with the dielectric film interposed therebetween.

Further, as an example according to the present embodiment, a semiconductor device may be mentioned in which the above-described capacitive element is formed on a base interlayer insulating film on a semiconductor substrate, and a first electrode of the capacitive element and a conductive plug formed in the base interlayer insulating film are connected.

The manufacturing method according to the fourth embodiment may also be grasped as follows: The method of manufacturing the surface-roughened electrode, according to the fourth embodiment, can be grasped as one in which in the manufacturing method of the first embodiment, a step for embedding the conductor inside the polycrystallized silicon film is further included following the migration step prior to the step for removing the polycrystallized silicon film.

### Fifth Embodiment

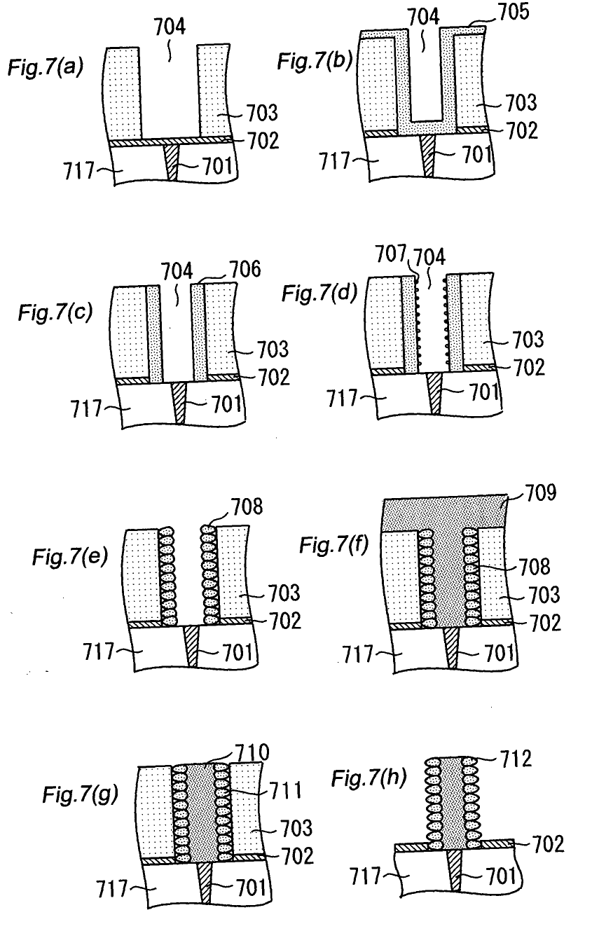

FIGS. 7(a) through 7(h) are respectively diagrams showing a method of manufacturing a semiconductor device, according to a fifth embodiment of the present invention, and fragmentary cross-sectional views showing a capacitor electrode and its a peripheral portion alone.

The method of manufacturing the semiconductor device, according to the fifth embodiment, particularly, a surface-roughened cylindrical electrode, a structure of a capacitor using the electrode and a manufacturing method thereof will be described with reference to FIGS. 7(a) through 7(h).

In FIG. 7(a), a plug-shaped conductor 701 connected to a lower conductive portion (not shown) is first formed in a base or underlying interlayer film 717. A stopper film (silicon nitride film) 702 is formed on the conductor plug 701. Further, an interlayer insulating film 703 composed of a silicon oxide film is formed thereon by a CVD method or the like. Thereafter, an opening 704 is defined in the interlayer film 703 by using a photolithography technology and a dry etching technology. In addition, the etching stopper film 702 at the bottom of the opening 704 is removed so that the opening 704 reaches the conductive plug 701.

Next, as shown in FIG. 7(b), an amorphous silicon film 705 is formed on the interlayer film 703 by the CVD method. The amorphous silicon film 705 is formed in a recess fashion along an inner surface of the opening 704.

Next, as shown in FIG. 7(c), anisotropic etching is done on the amorphous silicon film 705 to remove the amorphous silicon film 705 at the bottom of the opening 704 and leave the amorphous silicon film 705 at sidewall portions of the opening 704, thereby forming an amorphous silicon cylinder 706.

Next, as shown in FIG. 7(d), silicon growth nuclei 707 are formed on the amorphous silicon cylinder 706 by gas containing Si such as Si₂H₆ or the like. Subsequently, heat treatment is applied thereto at a temperature ranging from preferably 750° C. to 800° C., more preferably 770° C. to 800° C., to migrate silicon.

At this time, migration is generated up to the back side of a nuclei-applied surface under high-temperature processing at preferably 750° C. to 800° C., more preferably 770° C. to 800° C., as typically shown in FIG. 7(e) to polycrystallize the silicon, thereby forming a polycrystal silicon cylinder 708. Namely, amorphous silicon is migrated based on the growth nuclei until change of morphology occurs on the surface opposite to the surface formed with the growth nuclei changes. Consequently, the polycrystal silicon cylinder 708 is formed such that its inner surface decreases in surface roughness and its outer surface increases in surface roughness. Reducing the inner surface roughness in this way makes it possible to improve coverage where a conductor is embedded in the cylindrical inner side.

Next, as shown in FIG. 7(f), a conductor film 709 is formed on the interlayer film 703 and the polycrystal silicon cylinder 708 so as to bury the inside of the polycrystal silicon cylinder 708.

Next, as shown in FIG. 7(g), the conductor film 709 on the interlayer film 703 is removed by a CMP method or a dry etching method. Owing to this removal, an electrode, having a structure in which a conductor 710 is embedded in a surface-roughened cylinder 711 of the polycrystal silicon, is formed.

Next, as shown in FIG. 7(h), the interlayer film 703 is removed by chemical containing vapor-phase or liquid-phase hydrofluoric acid to thereby form a pillar surface-roughened electrode 712. Embedding the conductor 710 in the cylindrical inner side of the surface-roughened cylinder 711 in this way makes it possible to improve a physical strength. Since, for example, a metal conductor other than silicon is embedded as the conductor film 709 to bring the embedded conductor 710 and the conductor plug 701 into direct contact, a plug/electrode resistor and the resistance of the electrode per se can be reduced.

As described above, the present embodiment can prevent a short circuit between adjacent capacitor electrodes by leaving the interlayer film 703 as it is during surface-roughening processing of the surface of the electrode material without the need to take countermeasures for selectively forming the silicon growth nuclei as in the prior art. Increasing the surface roughness of the outer side of the pillar surface-roughened electrode 712 can ensure the capacitance of the capacitor. In the present embodiment, an improvement in the physical strength of the capacitor electrode, a reduction in the resistance of the electrode, and a reduction in the resistance between the lower plug and the capacitor electrode can be achieved by charging the conductor 710 inside the surface-roughened cylinder 711.

A structure of the present embodiment will next be explained in a summarized form as follows:

The surface-roughened electrode according to the present embodiment can be grasped as one in which, in the surface-roughened electrode (first electrode) shown in FIG. 3(f), the flat plate portion at its bottom is removed and the inner side of its cylindrical portion is buried with the conductor film.

Further, the surface-roughened electrode according to the present embodiment corresponds to the surface-roughened electrode (first electrode) 712 formed of the cylindrical portion 711 whose both sides are open, and the conductive film portion 710 that is buried inside the cylindrical portion 711. The surface-roughened electrode is one in which the surface of the cylindrical portion 710 of the electrode is subjected to surface-roughening processing and which is formed such that the rough-surface grain diameter of its outer surface is greater than that of its inner surface.

A capacitive element according to the present embodiment comprises the first electrode 712 formed as described above, a dielectric film formed on the outer surface of the first electrode, and a second electrode formed so as to be opposed to the first electrode with the dielectric film interposed there-between.

Further, as an example according to the present embodiment, a semiconductor device may be mentioned in which the above-described capacitive element is formed on a base interlayer insulating film on a semiconductor substrate, and a first electrode of the capacitive element and a conductive plug formed in the base interlayer insulating film are connected.

The manufacturing method according to the fifth embodiment can be also grasped as follows:

The method of manufacturing the surface-roughened electrode, according to the fifth embodiment, can be grasped as one in which, in the manufacturing method of the fourth embodiment, a step for removing the concave bottom of the amorphous silicon film is further included following the step for forming the amorphous silicon film and prior to the step for forming the silicon growth nuclei.

Next, as the method of manufacturing the surface-roughened electrode, according to the present invention, an amorphous silicon film may be processed by silicon etching chemicals such as a NH₄OH solution or the like after the amorphous silicon film has been migrated, in the first through fifth embodiments. Slightly etching the surface of the silicon film in this way and reducing contact portions between adjacent rough surface grains makes it possible to increase an exposed portion and enlarge a surface-roughened surface area.

The structure of the semiconductor device having the capacitor element such as a DRAM and its manufacturing method have been described by way of example in the first through fifth embodiments. However, the present invention can be grasped as a structure of a surface-roughened electrode and its manufacturing method. Further, the present invention may be grasped as a structure of a capacitive element having a surface-roughened electrode and its manufacturing method. In such a case, the present invention can be widely applied to an electronic device beyond a so-called semiconductor device.

The features and the advantages of the present invention may be summarized as follows.

In one aspect, in a semiconductor device according to the present invention and its manufacturing method, a process for surface-roughening an electrode material based on rough-surface growth nuclei is performed while an interlayer insulating film is being left behind in the case of a concave or cylindrical capacitor electrode. Afterwards, the interlayer insulating film is removed. Therefore, rough surface grains are not left between capacitor electrodes, thus making it possible to avoid the occurrence of a short circuit between the capacitor electrodes.

In another aspect, in a semiconductor device according to the present invention and its manufacturing method, nuclei are applied to an inner wall of a cylindrical electrode material in the case of a concave or cylindrical capacitor electrode. However, heating temperatures for surface-roughening processing are suitably selected to thereby grow rough surface grains so that a surface area of a cylindrical outer side increases, whereby irregularities of the cylindrical outer side can be increased as compared with those of a cylindrical inner side. Thus, coverage of a dielectric film or opposite electrode for the cylindrical inner side can be ensured and the capacitance of a capacitor can be ensured owing to surface roughness of the cylindrical outer side.

In another aspect, in a semiconductor device according to the present invention and its manufacturing method, if a cylindrical inner side is coated with a conductor after a rough surface is formed on the cylindrical outer side by surface-roughening processing of an electrode material in the case of a concave or cylindrical capacitor electrode, then a cylindrical capacitor can be improved in mechanical strength.

In another aspect, in a semiconductor device according to the present invention and its manufacturing method, surface-roughening processing of a cylindrical electrode material is executed before the removal of an interlayer insulating film in the case of a columnar or pillar capacitor electrode. Thereafter, the interlayer insulating film is removed after the inner part of a cylinder is charged with a conductor. Therefore, rough surface grains are not left between the adjacent capacitor electrodes, thus making it possible to avoid the occurrence of a short circuit between the capacitor electrodes.

In another aspect, in a semiconductor device according to the present invention and its manufacturing method, since the inner side of a cylinder is filled with a conductor after a cylindrical electrode material has been subjected to surface-roughening processing in the case of a columnar or pillar capacitor electrode, a cylindrical capacitor can be improved in mechanical strength.

In another aspect, in a semiconductor device according to the present invention and its manufacturing method, a metal conductor is charged inside a cylinder after execution of a rough-surface forming process requiring high-temperature processing for a cylindrical electrode material whose bottom is made open, in the case of a columnar or pillar capacitor electrode. In the case of such one as referred to above in this way, the capacitor electrode can be reduced in resistance. Further, such one, in which the charged conductor is brought into contact with a connecting plug, is capable of reducing interfacing resistance between the capacitor electrode and the connecting plug.

Incidentally, while the above description has been made with the capacitor electrode as the cylindrical or columnar type, it is for convenience. While a horizontal section of the capacitor electrode is normally set as circular, it may be modified without being limited to the circular form. Thus, it should be generally understood as cylindrical or columnar.

While the present invention described above is one typically applied to a memory device such as a DRAM having a capacitor, the present invention is not limited to it.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2002-244870, filed on Aug. 26, 2002 including specification, claims, drawings and summary, on which the Convention priority of the present application is based, are incorporated herein by reference in its entirety.

1. A semiconductor device comprising:
an electrode formed of a flat plate portion at a bottom thereof and a cylindrical portion which extends up continuously from the flat plate portion and whose one side is open, wherein a rough-surface grain diameter of an outer surface of said electrode is formed so as to be larger than a rough-surface grain diameter of an inner surface thereof.

2. The semiconductor device according to claim 1, wherein a conductor film is formed along the inner surface of said electrode.

3. The semiconductor device according to claim 1, wherein the inner side of said cylindrical portion is buried with a conductive film.

4. A semiconductor device comprising:
an electrode formed of a cylindrical portion and a conductive film buried in the inner side of said cylindrical portion, wherein a rough-surface grain diameter of an outer surface of said cylindrical portion is formed so as to be larger than a rough-surface grain diameter of an inner surface thereof.

5. A method of manufacturing a semiconductor device, comprising the steps of:
forming an opening in an interlayer insulating film disposed on a substrate;
forming an amorphous silicon film in a concave form along an inner surface of said opening;
forming silicon growth nuclei on the surface of said amorphous silicon film;
heat-treating said amorphous silicon film to migrate silicon and thereby polycrystallize said silicon film;
removing said polycrystallized silicon film on said interlayer insulating film; and
removing said interlayer insulating film and forming a cylindrical surface-roughened electrode.

6. The method of manufacturing a semiconductor device according to claim 5, further including a step for forming a conductor film in a concave fashion along an inner surface of said polycrystallized silicon film following said migration step.

7. The method of manufacturing a semiconductor device according to claim 5, further including the steps of:
forming a second amorphous silicon film in a concave form along an inner surface of said polycrystallized silicon film; and
heat-treating the second amorphous silicon film to migrate silicon and thereby polycrystallize said silicon film following said migration step.

8. The method of manufacturing a semiconductor device according to claim 5, further including a step for embedding a conductor inside said polycrystallized silicon film.

9. The method according to claim 8, further including a step of removing the bottom of said amorphous silicon film following said amorphous silicon film forming step.

10. The method according to claim 5, wherein after said migration step, the polycrystallized silicon film is processed by silicon etching chemicals.
